(19) United States
(12) Patent Application Publication
(10) Pub. No.: US 2009/0161328 A1
(43) Pub. Date: Jun. 25, 2009

(54) ELECTRONIC COMPONENTS MOUNTING ADHESIVE, MANUFACTURING METHOD OF AN ELECTRONIC COMPONENTS MOUNTING ADHESIVE, ELECTRONIC COMPONENTS MOUNTED STRUCTURE, AND MANUFACTURING METHOD OF AN ELECTRONIC COMPONENTS MOUNTED STRUCTURE

(75) Inventors: Tadahiko Sakai, Fukuoka (JP); Hideki Eifuku, Fukuoka (JP); Kouji Motomura, Saga (JP)

Correspondence Address: PEARNE & GORDON LLP, 1801 EAST 9TH STREET, SUITE 1200, CLEVELAND, OH, 44114-3108, US

(73) Assignee: MATSUSHITA ELECTRIC INDUSTRIAL CO., LTD., Osaka (JP)

(21) Appl. No.: 12/096,446

(22) PCT Filed: Sep. 13, 2007
(86) PCT No.: PCT/JP2007/068320

§ 371 Date: Jun. 6, 2008

(30) Foreign Application Priority Data
Sep. 15, 2006 (JP) 2006-251071

(51) Int. Cl. H05K 7/00; B23K 35/363; B23K 31/02

(52) U.S. Cl. 361/760; 148/24; 228/193

(57) ABSTRACT

An object is to provide an electronic components mounting adhesive capable of lowering the probability of occurrence of short-circuiting and increasing the reliability of the joining of electrodes in an electronic components mounted structure obtained by bonding electronic components to each other, as well as a manufacturing method of such an electronic components mounting adhesive, a resulting electronic component mounted structure, and a manufacturing method of such an electronic component mounted structure.

In an electronic components mounted structure 10, a first circuit board 11 and a second circuit board 13 are bonded to each other with an electronic components mounting adhesive 20. The electronic components mounting adhesive 20 is such that solder particles 22 are dispersed in a thermosetting resin 21. The solder particles 22 are subjected to heating treatment in an oxygen-containing atmosphere before being dispersed in the thermosetting resin 21. Electrodes 12 of the first circuit board 11 and electrodes 14 of the second circuit board 13 are electrically connected to each other by solder particles 22 that are sandwiched between the electrodes 12 and 14 and their surface oxide films 22a are thereby broken.

### TECHNICAL FIELD

The present invention relates to an electronic components mounting adhesive which is used for bonding electronic components to each other, a manufacturing method of an electronic components mounting adhesive, an electronic components mounted structure, and a manufacturing method of an electronic components mounted structure.

### BACKGROUND ART

Among electronic components mounted structures in which an electronic component such as a semiconductor chip or a circuit board is bonded to another electronic component are ones in which two electronic components are bonded to each other with an electronic components mounting adhesive in which solder particles are dispersed in a thermosetting resin. In such electronic components mounted structures, the two electronic components are bonded to each other strongly with a hardened member obtained through thermal setting of the thermosetting resin in the space between the two electronic components and, at the same time, electrodes of the two electronic components are electrically connected to each other by molten solder particles contained in the thermosetting resin in a thermosetting process of the thermosetting resin.
[Patent document 1] JP-A-11-4064

### DISCLOSURE OF THE INVENTION

However, since surface oxide films of the solder particles contained in the thermosetting resin are very thin, the surface oxide films are easily broken when, for example, solder particles collide with each other. A solder particle that has been melted by heating tends to be combined with another molten solder particle to form a large solder particle. Therefore, as shown in FIG. 3, when electronic components 11 and 13 are bonded to each other with an electronic components mounting adhesive in which solder particles 2 are dispersed in a thermosetting resin 1, electrodes 12 and 14 between which solder particles 2 having ordinary sizes are sandwiched are connected to each other normally but electrodes 12 and 14 between which a solder particle 2′ that is increased in size due to combining of plural solder particles 2 is sandwiched have an excessive amount of solder. As a result, a solder bridge B may be formed between adjoining pairs of electrodes 12 and 14. This means a problem of short-circuiting.

Furthermore, the surface of each solder particle 2 has a number of minute asperities. If water is attached to the surface of a solder particle 2, a phenomenon is prone to occur that the water is evaporated when the thermosetting resin 1 is set thermally and a void is formed between a hardened member of the thermosetting resin 1 and the surface of the semiconductor particle 2. If a void is formed on the surface of a semiconductor particle 2 that is sandwiched between electrodes 12 and 14 that are opposed to each other, the contact area of the electrodes 12 and 14 becomes small, which leads to a problem that the reliability of the joining of the electrodes 12 and 14 is lowered.

An object of the present invention is therefore to provide an electronic components mounting adhesive capable of lowering the probability of occurrence of short-circuiting and increasing the reliability of the joining of electrodes in an electronic components mounted structure obtained by bonding electronic components to each other, as well as a manufacturing method of such an electronic components mounting adhesive, a resulting electronic component mounted structure, and a manufacturing method of such an electronic component mounted structure.

According to the invention, an electronic components mounting adhesive includes: a thermosetting resin and solder particles dispersed in the thermosetting resin, the solder particles being subjected heating treatment in an oxygen-containing atmosphere before being dispersed in the thermosetting resin.

According to the invention, a manufacturing method of an electronic components mounting adhesive includes a step of: subjecting solder particles to heating treatment in an oxygen-containing atmosphere; and dispersing said solder particles in a thermosetting resin.

Further, according to the invention, an electronic components mounted structure includes: an electrode of a first electronic component and an electrode of a second electronic component; and an adhesive-hardened member that is obtained through thermal setting of an electronic components mounting adhesive mainly made of a thermosetting resin, wherein said electrode of the first electronic component and said electrode of the second electronic component are electrically connected to each other and the first and second electronic components are bonded to each other with, the adhesive-hardened member contains solder particles that were dispersed in the thermosetting resin after being subjected to heating treatment in an oxygen-containing atmosphere; and that the electrodes of the first electronic component and the electrodes of the second electronic component are electrically connected to each other by solder particles that are sandwiched between the electrodes and whose surface oxide films are thereby broken.

Further, according to the invention, a manufacturing method of an electronic components mounted structure in which electrodes of a first electronic component and electrodes of a second electronic component are electrically connected to each other and the first and second electronic components are bonded to each other with an adhesive-hardened member that is obtained through thermal setting of an electronic components mounting adhesive mainly made of a thermosetting resin, characterized by comprising: an adhesive applying step of applying an electronic components mounting adhesive to a first electronic component so that electrodes of the first electronic component are covered with it; and a thermal pressure bonding step of bonding the first electronic component and a second electronic component to each other by thermally setting the electronic components mounting adhesive by heating the first and second electronic components after the electrodes of the first electronic component and electrodes of the second electronic component are positioned with respect to each other and the first and second electronic components are brought closer to each other relatively so that the electrodes come into close proximity to each other, wherein the electronic components mounting adhesive which is applied to the first electronic component in the adhesive applying step contains solder particles that were dispersed in the thermosetting resin after being subjecting to heating treatment in an oxygen-containing atmosphere; and when the first and second electronic components are brought closer to each other relatively so that the electrodes come into close proximity to each other in the thermal pressure bonding step, solder particles are sandwiched between the electrodes and surface oxide films of the solder particles are thereby broken, whereby the electrodes are electrically connected to each other by the solder particles whose surface oxide films have been broken.

In the electronic components mounting adhesive according to the invention, the solder particles dispersed in the thermosetting resin were subjected to heating treatment in an oxygen-containing atmosphere before being dispersed in the thermosetting resin. Therefore, the surface oxide films of the surfaces of the solder particles are thicker than those of solder particles that were not subjected to heating treatment (i.e., oxide films formed by exposing solder particles to air without subjecting those to heating treatment in an oxygen-containing atmosphere). Such thick oxide films are not broken when the thermosetting resin is rendered flowable before being set thermally and the solder particles merely collide with each other. Such thick oxide films are broken only when the electronic components mounting adhesive is used for bonding the electronic components and the solder particles are crushed being sandwiched between the confronting electrodes.

Therefore, in the electronic components mounted structure in which the electronic components are bonded to each other with the electronic components mounting adhesive according to the invention and the adhesive-hardened member of the electronic components mounting adhesive according to the invention is interposed between the electronic components, no bridge is formed between adjoining pairs of electrodes by a large solder particle formed by combining of solder particles in contrast to the case where electronic components are bonded to each other with a conventional electronic components mounting adhesive whose solder particles were not subjected to heating treatment in an oxygen-containing atmosphere before being dispersed in a thermosetting resin. As a result, the probability of occurrence of short-circuiting in the electronic components mounted structure can be decreased greatly.

Furthermore, subjecting the solder particles to heating treatment can evaporate water that is attached to the surfaces of the solder particles before they are dispersed in the thermosetting resin. Therefore, no voids are formed on the surfaces of the solder particles when the thermosetting resin is set thermally. This prevents reduction of the contact areas of solder particles and the electrodes and can thereby increase the reliability of the joining of the electrodes.

### BRIEF DESCRIPTION OF THE DRAWINGS

FIG. 1 is a sectional view of part of an electronic components mounted structure according to an embodiment of the invention.

FIG. 2 illustrates a manufacturing process of an electronic components mounted structure according to the embodiment of the invention.

FIG. 3 is a sectional view of part of a conventional electronic component mounted structure.

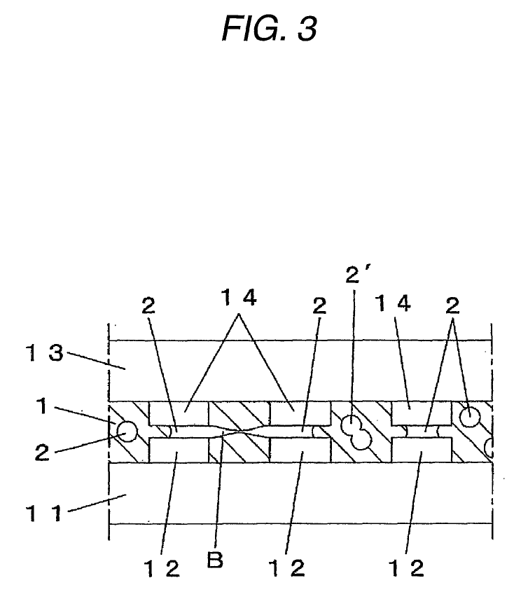

### BEST MODE FOR CARRYING OUT THE INVENTION

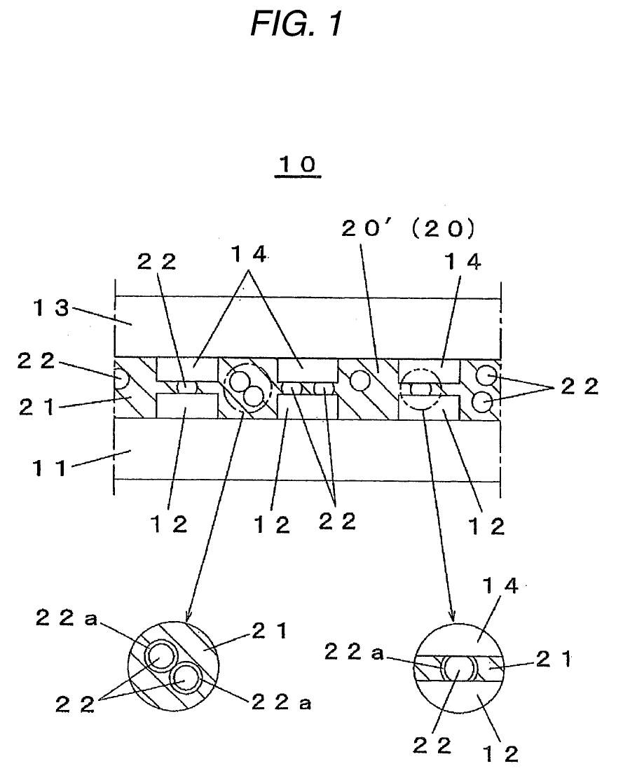

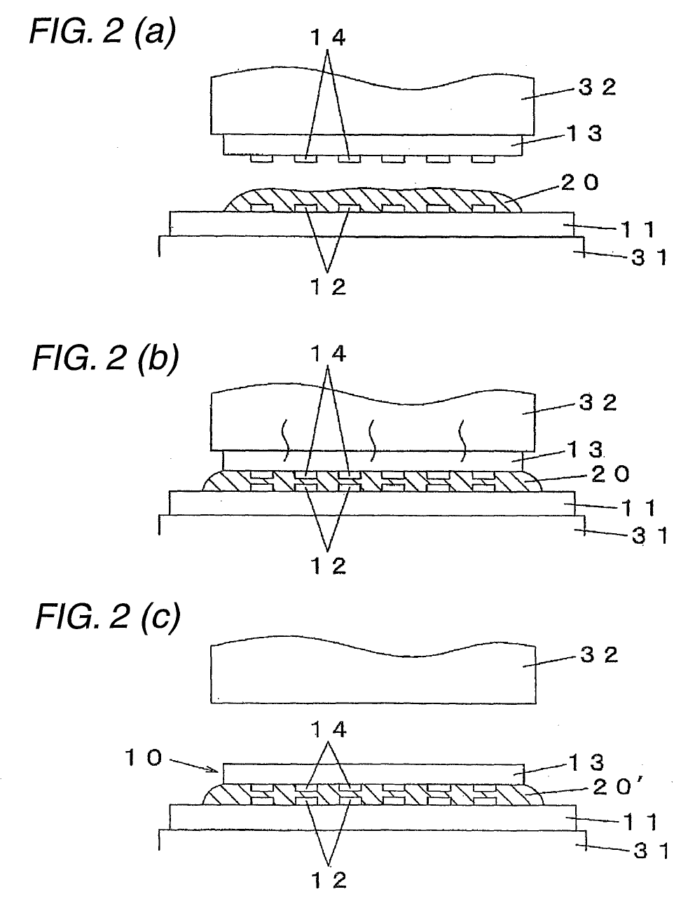

An embodiment of the present invention will be hereinafter described with reference to the drawings. FIG. 1 is a sectional view of part of an electronic components mounted structure according to the embodiment of the invention. FIG. 2 illustrates a manufacturing process of an electronic components mounted structure according to the embodiment of the invention.

As shown in FIG. 1, an electronic components mounted structure 10 is such that electrodes 12 of a first circuit board 11 and electrodes 14 of a second circuit board 13 are electrically connected to each other and the two circuit boards 11 and 13 are bonded to each other with an adhesive-hardened member 20′ that is obtained through thermal setting of an electronic components mounting adhesive (hereinafter referred to simply as “adhesive”) 20 mainly made of a thermosetting resin 21. The first circuit board 11 and the second circuit board 13 are examples of electronic components. Examples of the electronic components, other than a circuit board, are a semiconductor chip, a resistor, and a capacitor.

A manufacturing procedure of the electronic components mounted structure 10 will be described with reference to FIG. 2. First, after a first circuit board 11 is held on a holding stage 31 with the electrodes 12 up, adhesive 20 is applied to the surface of the first circuit board 11 by a dispenser or the like (see FIG. 2(a)). This is done so that all the electrodes 12 of the first circuit board 11 are covered with the adhesive 20. For example, a thermosetting resin 21 as the main component of the adhesive 20 is an epoxy resin, an acrylic resin, or the like. It is assumed that the melting point Mp of solder particles 22 is lower than or equal to the thermosetting temperature of the thermosetting resin 21.

After the adhesive 20 has been applied to the surface of the first circuit board 11, a thermal pressure bonding head 32 on which a second circuit board 13 is absorbed is placed over the first circuit board 11. After the electrodes 12 of the first circuit board 11 and the electrodes 14 of the second circuit board 13 are positioned with respect to each other, the second circuit board 13 is brought closer to the first circuit board 11 relatively (the thermal pressure bonding head 32 is lowered) so that the electrodes 14 of the second circuit board 13 come into close proximity to the electrodes 12 of the first circuit board 11 from above. Then, the two circuit boards 11 and 13 are heated (see FIG. 2(b)). As a result, the adhesive 20 between the two circuit boards 11 and 13 is thermally set and becomes an adhesive-hardened member 20′, whereby the two circuit boards 11 and 13 are bonded to each other strongly. In this thermal pressure bonding process, the electrodes 12 of the first circuit board 11 and the electrodes 14 of the second circuit board 13 crush the solder particles 22 in those portions of the adhesive 20 (adhesive-hardened member 20′) which are sandwiched between themselves, whereby surface oxide films 22a of the solder particles 22 are broken and the electrodes 12 and 14 are electrically connected to each other by the solder particles 22 that are melted by the heating (see the right-hand partial enlarged view in FIG. 1).

After a lapse of a prescribed time, the heating of the two circuit boards 11 and 13 is stopped, the absorbing of the second circuit board 13 is canceled, and the thermal pressure bonding head 32 is retreated upward. The manufacture of the electronic components mounted structure 10 is thus completed (see FIG. 2(c)).

As described above, the adhesive-hardened member 20′ of the electronic components mounted structure 10 is a member obtained by thermally setting the adhesive 20 in which the solder particles 22 are dispersed in the thermosetting resin 21. Not only is the adhesive-hardened member 20′ interposed between the first circuit board 11 and the second circuit board 13 to bond them strongly, but also solder particles 22 contained in the adhesive-hardened member 20′ are interposed between the electrodes 12 of the first circuit board 11 and the electrodes 14 of the second circuit board 13 and connect the two circuit electrodes 12 and 14 electrically. That is, in this embodiment, the adhesive 20 (adhesive-hardened member 20′) functions as what is called an anisotropic conductive member: whereas the electrodes 12 and 14 that are opposed to each other in the vertical direction are electrically connected to each other via the solder particles 22, adjoining pairs of electrodes 12 and 14 are electrically insulated from each other.

The adhesive 20 is manufactured by a manufacturing method including a process of dispersing the solder particles 22 in the thermosetting resin 21. Before the solder particles 22 are dispersed in the thermosetting resin 21, the solder particles 22 are subjected to heating treatment in an oxygen-containing atmosphere such as air. That is, the solder particles 22 contained in the adhesive 20 are ones that were subjected to heating treatment in an oxygen-containing atmosphere before being dispersed in the thermosetting resin 21.

Usually, the surfaces of solder particles are covered with oxide films that were formed by exposure to air before being dispersed in a thermosetting resin 21. In the adhesive 20 according to the embodiment in which the solder particles 22 were subjected to heating treatment in an oxygen-containing atmosphere before being dispersed in the thermosetting resin 21, the surface oxide films 22a of the solder particles 22 are thicker than the surface oxide films of the solder particles that were not subjected to heating treatment. For example, where the initial oxygen concentration is 100 ppm, the post-heating-treatment oxygen concentration becomes 150 ppm which is 1.5 times higher than the original value in the case of an Sn—Pb eutectic solder and becomes 200 ppm which is 2 times higher than the original value in the case of an Sn—Zn solder. As the oxygen concentration is increased in this manner, the surface oxide films 22a of the solder particles 22 become thicker. Such thick oxide films 22a are not broken when the thermosetting resin 21 is rendered flowable before being set thermally and the solder particles 22 merely collide with each other (see the left-hand partial enlarged view in FIG. 1). Such thick oxide films 22a are broken only when the adhesive 20 is used for bonding the first circuit board 11 and the second circuit board 13 and the solder particles 22 are crushed being sandwiched between the confronting electrodes 12 and 14, whereby the solders 22 connect the electrodes 12 and 14 of the two circuit boards 11 and 13 (see the right-hand enlarged view in FIG. 1).

Therefore, in the electronic components mounted structure 10 in which the first circuit board 11 and the second circuit board 13 are bonded to each other with the adhesive 20 according to the embodiment and the adhesive-hardened member 20′ is interposed between the first circuit board 11 and the second circuit board 13, no bridge is formed between adjoining pairs of electrodes 12 and 14 by a large solder particle formed by combining of solder particles 22 in contrast to the case where electronic components are bonded to each other with a conventional electronic components mounting adhesive whose solder particles were not subjected to heating treatment in an oxygen-containing atmosphere before being dispersed in a thermosetting resin. As a result, the probability of occurrence of short-circuiting in the electronic components mounted structure 10 can be decreased greatly.

The heating of the solder particles 22 in an oxidizing atmosphere which is performed before they are dispersed in the thermosetting resin 21 may be performed under any conditions as long as the above-described effect is obtained by making the thickness of the oxide films 22a greater than the ordinary value (i.e., the thickness of oxide films formed by exposing solder particles to air without subjecting those to heating treatment in an oxygen-containing atmosphere). However, to reliably produce oxide films 22a that are thick enough not to be broken when the solder particles merely collide with each other and to be broken only when the solder particles 22 are crushed being sandwiched between the confronting electrodes 12 and 14, it is preferable that the heating be performed at a temperature that is higher than or equal to 80° C. for 10 minutes or more.

Heating the solder particles 22 at a temperature that is higher than or equal to 100° C. for 10 minutes or more can evaporate water that is attached to the surfaces of the solder particles 22 before they are dispersed in the thermosetting resin 21. If the water that is attached to the surfaces of the solder particles 22 is evaporated before they are dispersed in the thermosetting resin 21, no voids are formed on the surfaces of the solder particles 22 when the thermosetting resin 21 is thereafter set thermally. This prevents reduction of the contact areas of solder particles 22 and the electrodes 12 and 24 and can thereby increase the reliability of the joining of the electrodes 12 and 14.

### INDUSTRIAL APPLICABILITY

The invention can lower the probability of occurrence of short-circuiting and increase the reliability of the joining of electrodes in an electronic components mounted structure.

1. An electronic components mounting adhesive comprising:
a thermosetting resin; and
solder particles dispersed in said thermosetting resin, the solder particles being subjected heating treatment in an oxygen-containing atmosphere before being dispersed in the thermosetting resin.

2. A manufacturing method of an electronic components mounting adhesive including a step of:
subjecting solder particles to heating treatment in an oxygen-containing atmosphere; and
dispersing said solder particles in a thermosetting resin.

3. An electronic components mounted structure comprising:
an electrode of a first electronic component and an electrode of a second electronic component; and
an adhesive-hardened member that is obtained through thermal setting of an electronic components mounting adhesive mainly made of a thermosetting resin,
wherein said electrode of the first electronic component and said electrode of the second electronic component are electrically connected to each other and the first and second electronic components are bonded to each other with,
the adhesive-hardened member contains solder particles that were dispersed in the thermosetting resin after being subjected to heating treatment in an oxygen-containing atmosphere; and
that the electrodes of the first electronic component and the electrodes of the second electronic component are electrically connected to each other by solder particles that are sandwiched between the electrodes and whose surface oxide films are thereby broken.

4. A manufacturing method of an electronic components mounted structure in which electrodes of a first electronic component and electrodes of a second electronic component are electrically connected to each other and the first and second electronic components are bonded to each other with an adhesive-hardened member that is obtained through thermal setting of an electronic components mounting adhesive mainly made of a thermosetting resin, characterized by comprising:
an adhesive applying step of applying an electronic components mounting adhesive to a first electronic component so that electrodes of the first electronic component are covered with it; and
a thermal pressure bonding step of bonding the first electronic component and a second electronic component to each other by thermally setting the electronic components mounting adhesive by heating the first and second electronic components after the electrodes of the first electronic component and electrodes of the second electronic component are positioned with respect to each other and the first and second electronic components are brought closer to each other relatively so that the electrodes come into close proximity to each other,
wherein the electronic components mounting adhesive which is applied to the first electronic component in the adhesive applying step contains solder particles that were dispersed in the thermosetting resin after being subjecting to heating treatment in an oxygen-containing atmosphere; and
when the first and second electronic components are brought closer to each other relatively so that the electrodes come into close proximity to each other in the thermal pressure bonding step, solder particles are sandwiched between the electrodes and surface oxide films of the solder particles are thereby broken, whereby the electrodes are electrically connected to each other by the solder particles whose surface oxide films have been broken.
